(19) United States
(12) Patent Application Publication
(10) Pub. No.: US 2025/0084307 A1
(43) Pub. Date: Mar. 13, 2025

(54) QUANTUM DOT AND DISPLAY DEVICE INCLUDING THE SAME

(71) Applicant: Samsung Display Co., LTD., Yongin-si (KR)

(72) Inventors: Youngsik KIM, Yongin-si (KR); Sungjae KIM, Yongin-si (KR); Bitna YOON, Yongin-si (KR); Donghee LEE, Yongin-si (KR); Taekjoon LEE, Yongin-si (KR); Junehyuk JUNG, Yongin-si (KR)

(21) Appl. No.: 18/825,620

(22) Filed: Sep. 5, 2024

Related U.S. Application Data
(63) Continuation-in-part of application No. 18/618,266, filed on Mar. 27, 2024, now abandoned.

(30) Foreign Application Priority Data
Sep. 12, 2023 (KR) 10-2023-0121371
Jun. 19, 2024 (KR) 10-2024-0079600

(51) Int. Cl. C09K 11/62; B82Y 20/00; B82Y 40/00; C09K 11/02; H10K 59/38

(52) U.S. Cl. CPC C09K 11/623; C09K 11/025; H10K 59/38; B82Y 20/00; B82Y 40/00

(57) ABSTRACT

A quantum dot includes a core including copper, indium, gallium, silver, and sulfur and a shell surrounding the core and including zinc sulfide (ZnS). A display device includes: a base layer; a circuit layer on the base layer; and a display element layer on the circuit layer, the display element layer including: a first electrode; a second electrode; and a light emitting layer between the first electrode and the second electrode and including the quantum dot.

### CROSS-REFERENCE TO RELATED APPLICATION

The present application is a continuation-in-part of U.S. patent application Ser. No. 18/618,266, filed Mar. 27, 2024, which claims priority to and the benefit of Korean Patent Application No. 10-2023-0121371, filed on Sep. 12, 2023, and Korean Patent Application No. 10-2024-0079600, filed on Jun. 19, 2024, the entire content of each of which are hereby incorporated by reference.

### BACKGROUND

### 1. Field

Embodiments of the present disclosure relate to a quantum dot and a display device. For example, embodiments of the present disclosure relate to a quantum dot including a core and a shell and a display device including the quantum dot.

### 2. Description of the Related Art

Various display devices applied to multimedia devices, such as televisions, mobile phones, tablet computers, navigation devices, and game devices, are being developed. Quantum dots are used to form a light emitting element or to convert a property of a source light in the display devices.

### SUMMARY

Embodiments of the present disclosure provide a quantum dot including a core including copper, indium, gallium, sulfur, and silver and a shell and having a high color purity and a high photostability.

Embodiments of the present disclosure provide a display device including the quantum dot and having a high reliability.

Embodiments of the present disclosure provide a quantum dot including a core including copper, indium, gallium, silver, and sulfur and a shell surrounding the core and including zinc sulfide (ZnS).

The quantum dot may emit a green light having a center wavelength equal to or greater than about 500 nm and equal to or smaller than about 550 nm, the quantum dot including the core and the shell has a diameter equal to or greater than about 2 nm and equal to or smaller than about 4 nm, and a ratio of a number of moles of the silver to a sum of a number of moles of the silver and the copper may be equal to or greater than about 0.001 and equal to or smaller than about 0.200.

The quantum dot may emit a red light having a center wavelength equal to or greater than about 580 nm and equal to or smaller than about 660 nm, the quantum dot including the core and the shell may have a diameter equal to or greater than about 5 nm and equal to or smaller than about 10 nm, and a ratio of a number of moles of the silver to a sum of a number of moles of the silver and the copper may be equal to or greater than about 0.001 and equal to or smaller than about 0.200. A light emitted from the quantum dot has a full-width at half-maximum (FWHM) equal to or greater than about 25 nm and equal to or smaller than about 60 nm.

The quantum dot further includes at least one outer shell surrounding the shell.

The at least one outer shell includes ZnSe, ZnS, ZnTe, ZnO, ZnMg, ZnMgSe, ZnMgS, ZnMgAg, GaSe, GaTe, GaP, GaAs, GaSb, InAs, InSb, AlP, AlAs, AlSb, MnS, MnSe, MgS, and/or MgSe.

The shell has a thickness of about 0.5 nm to about 3 nm, and the outer shell has a thickness of about 0.5 nm to about 4 nm.

The outer shell has a thickness greater than a thickness of the shell.

A ratio of a mass of the shell to a sum of masses of the core and the shell is equal to or greater than about 0.2 and equal to or smaller than about 0.8.

The quantum dot further includes an organic ligand and/or a metal halide ligand bound to a surface of the quantum dot the quantum dot may emit a green light having a full-width at half-maximum (FWHM) equal to or greater than about 25 nm and equal to or smaller than about 60 nm and a center wavelength equal to or greater than about 500 nm and equal to or smaller than about 550 nm or a red light having a full-width at half-maximum (FWHM) equal to or greater than about 25 nm and equal to or smaller than about 60 nm and having a center wavelength equal to or greater than about 580 nm and equal to or smaller than about 660 nm, and a ratio of a mass of the gallium to a mass of the indium is within a range of about 0.2 to about 2.0.

Embodiments of the present disclosure provide a display device including a display panel that provides a source light and a light control member on the display panel and including a light control layer including a plurality of light control portions and a dividing pattern that allows the light control portions to be distinguished from each other. At least one of the light control portions includes a quantum dot, and the quantum dot includes a core including copper, indium, gallium, silver, and sulfur and a shell surrounding the core and including zinc sulfide (ZnS). The quantum dot may emit a green light having a full-width at half-maximum (FWHM) equal to or greater than about 25 nm and equal to or smaller than about 60 nm and a center wavelength equal to or greater than about 500 nm and equal to or smaller than about 550 nm, and a ratio of a number of moles of the silver to a sum of a number of moles of the silver and the copper is equal to or greater than about 0.01 and equal to or smaller than about 0.10.

The quantum dot may emit a red light having a full-width at half-maximum (FWHM) equal to or greater than about 25 nm and equal to or smaller than about 60 nm and a center wavelength equal to or greater than about 580 nm and equal to or smaller than about 660 nm, and a ratio of a number of moles of the silver to a sum of a number of moles of the silver and the copper is equal to or greater than about 0.01 and equal to or smaller than about 0.20. A light emitted from the quantum dot may have a full-width at half-maximum (FWHM) equal to or greater than about 25 nm and equal to or smaller than about 50 nm, and a ratio of a number of moles of the silver to a sum of a number of moles of the silver and the copper is equal to or greater than about 0.001 and equal to or smaller than about 0.05.

The core includes, based on a total weight of the core of about 100 wt %, the copper in an amount equal to or greater than about 5 wt % and equal to or smaller than about 20 wt %, the indium in an amount equal to or greater than about 10 wt % and equal to or smaller than about 30 wt %, the gallium in an amount equal to or greater than about 10 wt % and equal to or smaller than about 40 wt %, the sulfur in an amount equal to or greater than about 30 wt % and equal to or smaller than about 60 wt %, and the silver in an amount equal to or greater than about 5 wt % and equal to or smaller than about 30 wt %.

The light control member further includes a base substrate and a color filter layer including a plurality of filters that transmit lights having different wavelengths.

The light control portions are between the display panel and the color filter layer, and the color filter layer is between the light control portions and the base substrate.

The light control portions include a first light control portion that transmits the source light, a second light control portion that converts the source light to a second color light and emits the second color light, and a third light control prior that converts the source light to a third color light and emits the third color light.

The source light is a blue light.

The second and third light control portions include the quantum dot.

The second color light may have a center wavelength equal to or greater than about 500 nm and equal to or smaller than about 550 nm, and the quantum dot may emit a green light having a full-width at half-maximum (FWHM) equal to or greater than about 25 nm and equal to or smaller than about 60 nm.

The third color light has a center wavelength equal to or greater than about 580 nm and equal to or smaller than about 660 nm, and the quantum dot emits a red light having a full-width at half-maximum (FWHM) equal to or greater than about 25 nm and equal to or smaller than about 60 nm.

The quantum dot further includes at least one outer shell surrounding the shell.

The at least one outer shell includes ZnSe, ZnS, ZnTe, ZnO, ZnMg, ZnMgSe, ZnMgS, ZnMgAg, GaSe, GaTe, GaP, GaAs, GaSb, InAs, InSb, AlP, AlAs, AlSb, MnS, MnSe, MgS, and/or MgSe.

According to the above, the quantum dot includes the core including copper, indium, gallium, sulfur, and silver and the shell having a suitable or sufficient thickness and thus exhibits a high color purity and a high photostability.

According to the above, the display device includes the quantum dot and thus has excellent display quality and excellent reliability.

### BRIEF DESCRIPTION OF THE DRAWINGS

The above and other features of embodiments of the present disclosure will become readily apparent by reference to the following detailed description when considered in conjunction with the accompanying drawings wherein:

FIG. 1 is a perspective view of an electronic device according to an embodiment of the present disclosure;

FIG. 2 is an exploded perspective view of an electronic device according to an embodiment of the present disclosure;

FIG. 3A is a view schematically illustrating a structure of a quantum dot according to an embodiment of the present disclosure;

FIG. 3B is a view schematically illustrating a structure of a quantum dot according to an embodiment of the present disclosure;

FIG. 4 is an enlarged plan view of a display device according to an embodiment of the present disclosure;

FIG. 5 is a cross-sectional view of a display device taken along a line I-I′ of FIG. 4 according to an embodiment of the present disclosure;

FIG. 6A is a graph illustrating a photoluminescence spectrum with respect to a quantum dot according to comparative example 1;

FIG. 6B is a graph illustrating a photoluminescence spectrum with respect to a quantum dot according to comparative example 2;

FIGS. 7A-7D are graphs illustrating a photoluminescence spectrum with respect to a quantum dot according to an embodiment of the present disclosure;

FIGS. 8A-8C are graphs illustrating a photoluminescence spectrum with respect to a quantum dot according to an embodiment of the present disclosure;

FIGS. 9A-9E are graphs illustrating a photoluminescence spectrum with respect to a quantum dot according to an embodiment of the present disclosure; and

FIGS. 10A-10C are graphs illustrating a photoluminescence spectrum with respect to a quantum dot according to an embodiment of the present disclosure.

### DETAILED DESCRIPTION

Hereinafter, embodiments of the present disclosure will be described with reference to the accompanying drawings.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components may be exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the spirit or scope of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the present disclosure, when an element is referred to as being “directly on” another element, there are no intervening elements present therebetween, such as a layer, a film, a region, and a substrate. For example, the term “directly on” may mean that two layers or two members are providing without employing additional adhesive therebetween.

In the present disclosure, the term “group” refers to a group in the IUPAC periodic table.

In the present disclosure, “group II” includes group IIA elements and group IIB elements. As an example, the group II elements may be, but are not limited to, magnesium (Mg) and/or zinc (Zn).

In the present disclosure, “group III” includes group IIIA elements and group IIIB elements. As an example, the group III elements may be, but are not limited to, aluminum (AI), indium (In), gallium (Ga), and/or titanium (Ti).

In the present disclosure, “group V” includes group VA elements and group VB elements. As an example, the group V elements may be, but are not limited to, phosphorus (P), arsenic (As), and/or antimony (Sb).

In the present disclosure, “group VI” includes group VIA elements and group VIB elements. As an example, the group VI elements may be, but are not limited to, oxygen (O), sulfur (S), selenium (Se), and/or tellurium (Te).

In the present disclosure, “group VII” includes group VIIA elements and group VIIB elements. As an example, the group VII elements may be, but are not limited to, manganese (Mn).

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a quantum dot and a display device including the quantum dot according to embodiments of the present disclosure will be described with reference to the accompanying drawings.

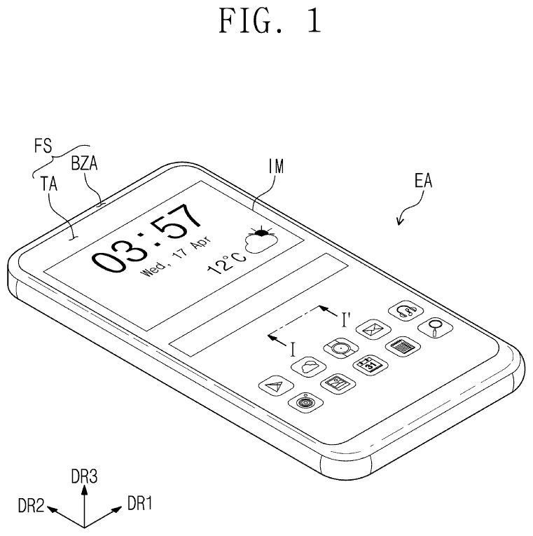

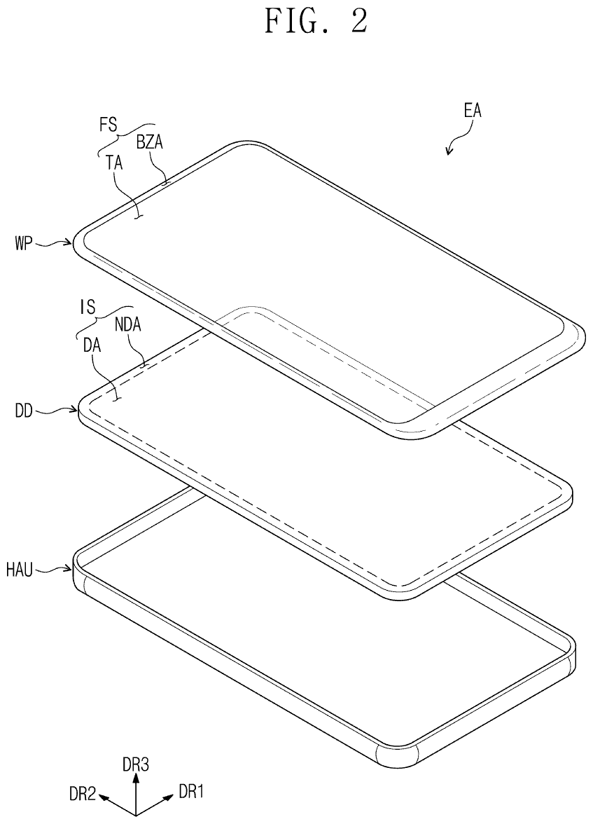

FIG. 1 is a perspective view of an electronic device EA according to an embodiment of the present disclosure. FIG. 2 is an exploded perspective view of the electronic device EA according to an embodiment of the present disclosure.

The electronic device EA may be applied to a large-sized display device, such as a television set, a monitor, an outdoor billboard, etc. In addition, the electronic device EA may be applied to a small and/or medium-sized display device, such as a personal computer, a notebook computer, a personal digital assistant, a car navigation unit, a game unit, a smart phone, a tablet computer, a camera, etc. However, these are merely examples, and the electronic device EA may be applied to other suitable display devices as long as they do not depart from the concept of the present disclosure. FIG. 1 shows the smart phone as a representative example of the electronic device EA.

In some embodiments, the electronic device EA may include a foldable display device including a folding area and a non-folding area and/or a bendable display device including at least one bending portion.

A front surface of the electronic device EA may correspond to a front surface of the display device DD and a front surface of a window WP. Accordingly, the front surface of the electronic device EA, the front surface of the display device DD, and the front surface of the window WP will be assigned with the same reference numeral, for example, “FS”.

Referring to FIG. 2, the electronic device EA may include the window WP, the display device DD, and a housing HAU.

The window WP may include an optically transparent insulating material (e.g., an optically transparent electrically insulating material). The window WP may include a transmissive area TA and a bezel area BZA.

The transmissive area TA may be an optically transparent area. In FIGS. 1-2, the transmissive area TA may have a quadrangular shape with rounded vertices, however, this is merely an example. The transmissive area TA may have a variety of suitable shapes and should not be particularly limited.

The bezel area BZA may be an area having a relatively lower light transmittance as compared with the transmissive area TA. The bezel area BZA may have a set or predetermined color. The bezel area BZA may be adjacent to the transmissive area TA and may surround the transmissive area TA. The bezel area BZA may define a shape of the transmissive area TA. However, the present disclosure should not be limited thereto or thereby, and the bezel area BZA may be adjacent to only one side of the transmissive area TA or may be omitted.

The display device DD may have a configuration that substantially generates an image IM. The display device DD may be under the window WP. In the present disclosure, the term “under” may mean a direction opposite to the direction to which the display device DD displays the image IM.

The display device DD may display the image IM through a display surface IS, and a user may view the image IM through the transmissive area TA corresponding to the front surface FS of the electronic device EA. The image IM may include a still image as well as a video. FIG. 1 shows a structure in which the front surface FS is substantially parallel to a plane defined by a first direction DR1 and a second direction DR2 intersecting the first direction DR1, however, this is merely an example. According to an embodiment, the front surface FS may be curved.

A third direction DR3 may indicate a normal line direction of the front surface FS of the electronic device EA (e.g., a direction perpendicular to the front surface FS), e.g., a direction in which the image IM is displayed in a thickness direction of the electronic device EA. In some embodiments, front (or upper) and rear (or lower) surfaces of each component of the electronic device EA may be distinguished from each other in the third direction DR3.

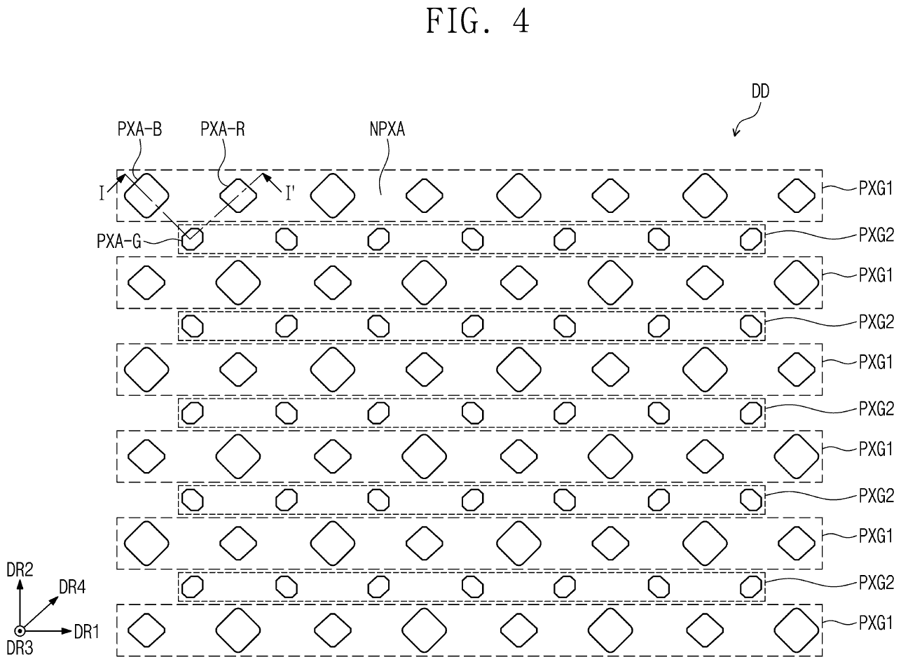

A fourth direction DR4 (refer to FIG. 4) may be a direction between the first direction DR1 and the second direction DR2. The fourth direction DR4 may be defined in a plane substantially parallel to the plane defined by the first direction DR1 and the second direction DR2. In some embodiments, directions indicated by the first, second, third, and fourth directions DR1, DR2, DR3, and DR4 are relative to each other, and thus, the directions indicated by the first, second, third, and fourth directions DR1, DR2, DR3, and DR4 may be changed to other directions.

The display device DD may include a display area DA and a non-display area NDA. The display area DA may be activated in response to electrical signals. The non-display area NDA may be covered by the bezel area BZA. The non-display area NDA may be defined adjacent to the display area DA. The non-display area NDA may surround the display area DA.

The housing HAU may be under the display device DD. The housing HAU may accommodate the display device DD. The housing HAU may cover a portion of the display device DD, and the upper surface of the display device DD, e.g., the display surface IS, may be exposed. The housing HAU may cover a side surface and a bottom surface of the display device DD, and the upper surface may be entirely exposed, however, the present disclosure should not be limited thereto or thereby. According to an embodiment, the housing HAU may cover a portion of the upper surface in addition to the side surface and the bottom surface of the display device DD.

The housing HAU may protect the display device DD from external impacts and a foreign substance. The housing HAU may include a plastic and/or metal material, however, this is merely an example. The material for the housing HAU should not be particularly limited as long as the material protects the display device DD from the external impacts and the foreign substance.

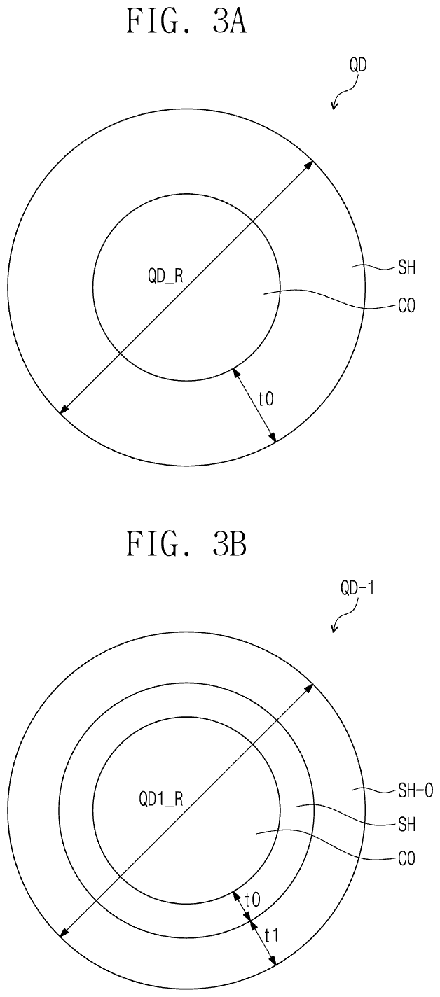

FIG. 3A is a view schematically illustrating a structure of a quantum dot QD according to an embodiment of the present disclosure. FIG. 3B is a view schematically illustrating a structure of a quantum dot QD-1 according to an embodiment of the present disclosure. The structure, components, and characteristics of embodiments of the quantum dots QD and QD-1 will be described with reference to FIGS. 3A and 3B.

Referring to FIG. 3A, the quantum dot QD may include a core CO and a shell SH surrounding the core CO.

The core CO may include copper (Cu), indium (In), gallium (Ga), silver (Ag), and sulfur (S). The core CO may be obtained by doping a CuInGaS compound with silver. According to an embodiment, copper (Cu) and silver (Ag) included in the core CO may exist at various suitable mole ratios.

In the present embodiment, a ratio of the number of moles of copper (Cu) to the number of moles of silver (Ag) constituting the core (CO) may be within a range from about 0.001 or more to about 0.999 or less or, for example, may be about 0.01 or more and about 0.99 or less.

In the present embodiment, a ratio of a mass of gallium (Ga) to a mass of indium (In) constituting the core CO may be about 0.2 or more and about 2.0 or less, for example, may be about 0.4 or more and about 1.7 or less, or may be about 0.47 or more and about 1.7 or less.

In the case of other quantum dots having a core of AgInGaS, a common method is to grow a shell of amorphous gallium sulfide (GaS) surrounding the core. However, the amorphous shell does not sufficiently protect the core, and thus, it is difficult to secure a stability of the quantum dot.

In addition, in other quantum dots having a core of CuInGaS₂, a common method is to grow a shell of zinc sulfide (ZnS) surrounding the core. When the quantum dot includes the core surrounded by the shell including zinc sulfide (ZnS), the stability of the quantum dot is improved, however, in this case, a full-width at half-maximum (FWHM) of the quantum dot increases due to optical characteristics of the core.

However, according to embodiments of the present disclosure, the core CO may include all of silver (Ag), copper (Cu), indium (In), gallium (Ga), and sulfur (S), and the shell SH including zinc sulfide (ZnS) may be grown outside of the core CO, thereby securing stability of the quantum dot. In addition, as the core CO includes silver (Ag), the luminescence FWHM may be reduced, and thus, a high color reproducibility may be achieved. Accordingly, the quantum dot QD may have a high quantum efficiency and an optical stability and may emit a light having a suitable or desired maximum photoluminescence wavelength at a narrow FWHM.

In some embodiments, the core CO may include, based on a total weight of the core CO, e.g., about 100 wt %, copper (Cu) in an amount equal to or greater than about 5 wt % and equal to or smaller than about 20 wt %, indium (In) in an amount equal to or greater than about 10 wt % and equal to or smaller than about 30 wt %, gallium (Ga) in an amount equal to or greater than about 10 wt % and equal to or smaller than about 40 wt %, sulfur (S) in an amount equal to or greater than about 30 wt % and equal to or smaller than about 60 wt %, and silver (Ag) in an amount equal to or greater than about 5 wt % and equal to or smaller than about 30 wt %.

In some embodiments, the content of elements included in the quantum dot QD may be measured by an inductively coupled plasma atomic emission spectroscopy (ICP-AES), however, the present disclosure should not be limited thereto or thereby.

In embodiments where the content of copper (Cu), indium (In), gallium (Ga), sulfur (S), and silver (Ag) included in the core CO satisfies the above-described range, the quantum dot QD may emit a high-color-purity green light having a center wavelength equal to or greater than about 500 nm and equal to or smaller than about 550 nm and a FWHM equal to or greater than about 25 nm and equal to or smaller than about 60 nm. According to an embodiment, the quantum dot QD may emit a high-color-purity red light with a center wavelength equal to or greater than about 580 nm and equal to or smaller than about 660 nm and the FWHM equal to or greater than about 25 nm and equal to or smaller than about 60 nm.

The shell SH may surround the core CO. The shell SH may be outside the core CO. The shell SH may surround the core CO and may be grown to have a uniform (or substantially uniform) thickness (t0). As an example, the thickness (t0) of the shell may be within a range of about 0.5 nm to about 3 nm. However, the thickness (t0) of the shell should not be limited thereto or thereby.

The shell SH may have a single-layer structure. As an example, the shell SH may have a single-layer structure of a single material or a single-layer structure of a plurality of different materials. FIG. 3A shows the quantum dot including the shell SH having a single-layer structure as a representative example. The ratio of the mass of the shell SH to the sum of the total masses of the core CO and the shell SH may be equal to or greater than about 0.2 and equal to or smaller than about 0.8.

However, the weight ratio of the shell SH to the quantum dot QD is merely an example, and the present disclosure should not be limited thereto or thereby.

The shell SH may include zinc sulfide (ZnS). The zinc sulfide (ZnS) has a lattice spacing in a similar range to a lattice spacing of compounds such as copper (Cu), indium (In), and sulfur (S) that constitute the core CO in the quantum dot QD, and accordingly, the shell SH may be formed of zinc sulfide (ZnS) to have a suitable or sufficient thickness outside the core CO while minimizing or reducing influences on the core CO.

As an example, a CuInS₂ compound may have a lattice spacing of about 5.52 Å, a CuGaS₂ compound may have a lattice spacing of about 5.33 Å, and a ZnS compound may have a lattice spacing of about 5.47 Å. Accordingly, the shell SH including zinc sulfide (ZnS) may surround the core CO including copper (Cu), indium (In), and sulfur (S) and may have suitable or sufficient thickness.

The quantum dot QD may include the shell SH having suitable or sufficient thickness, and the shell SH may provide an excellent passivation effect on the core CO. Therefore, the quantum dot QD may have improved reliability, and thus, may have high quantum yield characteristics.

Referring to FIG. 3B, the quantum dot QD-1 may include a core CO, a shell SH surrounding the core CO, and at least one outer shell SH—O surrounding the shell SH. The core CO and the shell SH of the quantum dot QD-1 correspond to the core CO and the shell SH described with reference to FIG. 3A, and thus, details of the core CO and the shell SH of the quantum dot QD-1 will not be repeated here.

The outer shell SH—O may completely surround the shell SH. Accordingly, a surface of the quantum dot QD-1 may be defined by an external surface of the outer shell SH—O. The shell SH may be covered by the outer shell SH—O and may not be exposed in the quantum dot QD-1.

The outer shell SH—O may have a single-layer or multi-layer structure. As an example, the shell SH may have a single-layer structure of a single material, a single-layer structure of a plurality of different materials, or a multi-layer structure of a plurality of layers including materials different from each other. In embodiments where the outer shell SH—O has the multi-layer structure, the plurality of layers may have different compositions. In some embodiments, the composition of each layer may vary discontinuously within the outer shell SH—O or may vary continuously within the outer shell SH—O. FIG. 3B shows the outer shell SH—O having the single-layer structure as a representative example, however, the present disclosure should not be limited thereto or thereby.

The outer shell SH—O may include at least one selected from ZnSe, ZnS, ZnTe, ZnO, ZnMg, ZnMgSe, ZnMgS, ZnMgAg, GaSe, GaTe, GaP, GaAs, GaSb, InAs, InSb, AlP, AlAs, AlSb, MnS, MnSe, MgS, and MgSe.

In the quantum dot QD-1, the shell SH may have a thickness (t0) within a range of about 0.5 nm to about 3 nm, and the outer shell SH—O may have a thickness (t1) within a range of about 0.5 nm to about 4 nm. The thickness (t1) of the outer shell SH—O may be greater than the thickness (t0) of the shell SH, however, the present disclosure should not be limited thereto or thereby.

The quantum dot QD-1 may include the shell SH and the outer shell SH—O and may provide an excellent passivation effect on the core CO. Therefore, the quantum dot QD-1 may have an excellent reliability and high quantum yield characteristics.

Referring to FIGS. 3A and 3B, the quantum dots QD and QD-1 may respectively have average diameters QD_R and QD1_R each of which is equal to or greater than about 5 nm and equal to or smaller than about 15 nm.

In embodiments where the diameters QD_R and QD1_R of the quantum dots QD and QD-1 satisfy the diameter range described above, the quantum dots QD and QD-1 may exhibit characteristic behaviors as quantum dots and may also have excellent dispersibility. In some embodiments, as the average diameter of the quantum dots QD and QD-1 is variously selected within the range described above, the photoluminescence wavelength of the quantum dots QD and QD-1 and/or semiconductor properties of the quantum dots QD and QD-1 may be suitably varied.

In embodiments of the present disclosure, the expression “a diameter of quantum dot” may refer to a diameter of an entire quantum dot including its core and shell.

In some embodiments, a shape of each of the quantum dots QD and QD-1 may be selected from shapes commonly used in the related art and should not be particularly limited. In some embodiments, the quantum dots QD and QD-1 may be a spherical, pyramidal, multi-arm, and/or cubic nanoparticles, nanotubes, nanowires, nanofibers, nanoplatelets, and/or the like. FIGS. 3A and 3B show the quantum dots QD and QD-1 each having the spherical shape as a representative example.

In some embodiments, the quantum dots QD and QD-1 may further include an organic ligand and/or metal halide ligand bound to a surface of the quantum dots QD and QD-1. The ligand may be chemically bound to the surface of the quantum dots QD and QD-1 and may passivate the quantum dots QD and QD-1. As an example, the quantum dot QD may further include the ligand chemically bound to the shell SH, and the quantum dot QD-1 may further include the ligand chemically bound to the outer shell SH—O.

The quantum dots QD and QD-1 may emit a green light. As an example, the quantum dots QD and QD-1 may emit a green light having a maximum photoluminescence wavelength equal to or greater than about 500 nm and equal to or smaller than about 550 nm.

According to an embodiment, the quantum dots QD and QD-1 may emit a red light. The quantum dots QD and QD-1 may emit the red light having a maximum photoluminescence wavelength equal to or greater than about 580 nm and equal to or smaller than about 660 nm.

The photoluminescence wavelength of the light emitted from the quantum dots QD and QD-1 may be controlled by adjusting a size of the core CO, the thickness of the shell SH, and the thickness of the outer shell SH—O.

The quantum dots QD and QD-1 may have a full-width at half-maximum (FWHM) of a narrow photoluminescence wavelength spectrum, which is equal to or Greater than about 25 nm and equal to or smaller than about 60 nm. As an example, the quantum dots QD and QD-1 may have a FWHM of an photoluminescence wavelength spectrum, which is equal to or greater than about 30 nm and equal to or smaller than about 60 nm. In some embodiments where the FWHM of the quantum dot QD satisfies the above-described range, a color purity and color reproducibility of the quantum dots QD and QD-1 may be improved. In some embodiments, the light emitted through the quantum dots QD and QD-1 may travel in all (or substantially all) directions, and thus, a light viewing angle may be improved.

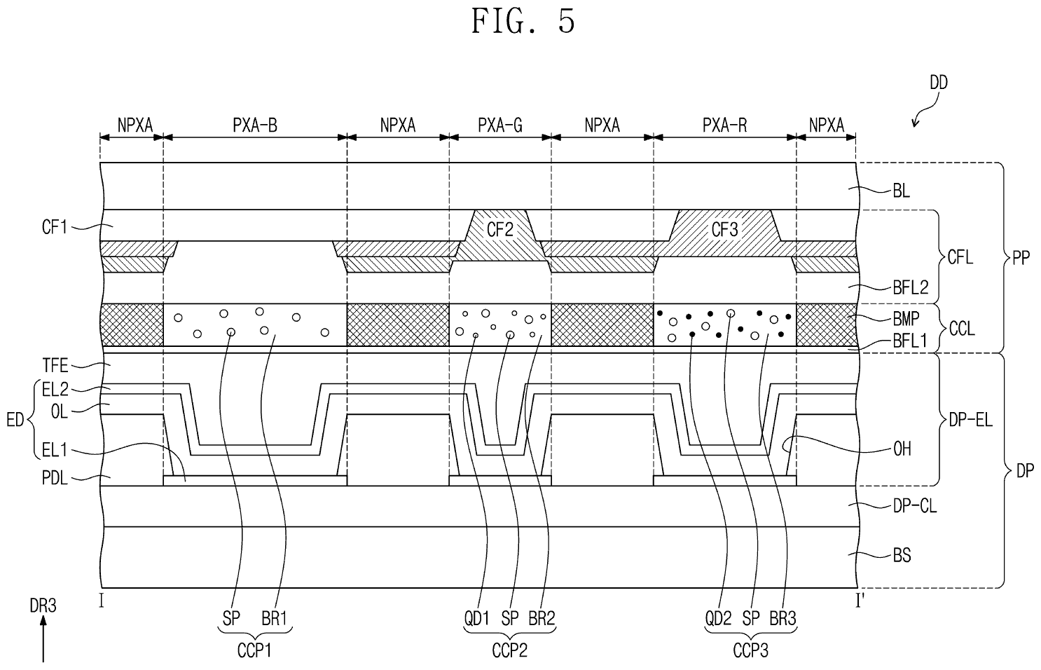

FIG. 4 is an enlarged plan view of a portion of the display device DD according to an embodiment of the present disclosure. FIG. 5 is a cross-sectional view of the display device DD taken along a line I-I′ of FIG. 4 according to an embodiment of the present disclosure.

Hereinafter, embodiments of the display devices DD will be described with reference to FIGS. 4 and 5. The display devices DD shown in FIGS. 4 and 5 may include the above-described quantum dots.

Referring to FIG. 4, the display device DD may include a non-light-emitting area NPXA and light emitting areas PXA-B, PXA-G, and PXA-R. The light emitting areas PXA-B, PXA-G, and PXA-R may be spaced apart from each other when viewed in the plane.

The light emitting areas PXA-B, PXA-G, and PXA-R may be distinguished from each other according to colors of lights transmitted therethrough. FIGS. 4-5 show three light emitting areas PXA-B, PXA-G, and PXA-R that respectively emit a blue light, a green light, and a red light as a representative example. As an example, the display device DD may include a blue light emitting area PXA-B, a green light emitting area PXA-G, and a red light emitting area PXA-R, which are distinguished from each other.

Referring to FIG. 4, the red light emitting area PXA-R may have a quadrangular shape with vertices cut straight, the green light emitting area PXA-G may have an octagonal shape, and the blue light emitting area PXA-B may have a quadrangular shape with vertices rounded, however, the present disclosure should not be limited thereto or thereby. According to an embodiment, each of the light emitting areas PXA-B, PXA-G, and PXA-R may have various suitable polygonal shapes or a circular shape (or a generally circular shape).

Referring to FIG. 4, the blue light emitting areas PXA-B and the red light emitting areas PXA-R may be alternately arranged with each other in the first direction DR1 to form a first group PXG1. The green light emitting areas PXA-G may be arranged in the first direction DR1 to form a second group PXG2. The first group PXG1 may be spaced apart from the second group PXG2 in the second direction DR2. Each of the first group PXG1 and the second group PXG2 may be provided in plural. The first groups PXG1 and the second groups PXG2 may be alternately arranged with each other in the second direction DR2. One green light emitting area PXA-G may be spaced apart from one blue light emitting area PXA-B or one red light emitting area PXA-R in the fourth direction DR4. The light emitting areas PXA-B, PXA-G, and PXA-R shown in FIG. 4 may be arranged in a PENTILE® arrangement structure (e.g., an RGBG matrix, RGBG structure, or RGBG matrix structure), but the present disclosure is not limited thereto. PENTILE® is a duly registered trademark of Samsung Display Co., Ltd.

However, the present disclosure should not be limited thereto or thereby, and the light emitting areas PXA-B, PXA-G, and PXA-R may be arranged in various suitable ways. For example, the light emitting areas PXA-B, PXA-G, and PXA-R may be arranged in a stripe form in which the blue light emitting area PXA-B, the green light emitting area PXA-G, and the red light emitting area PXA-R are sequentially and alternately arranged in the first direction DR1 or may be arranged in a DIAMOND PIXEL™ arrangement structure. DIAMOND PIXEL™ is a trademark of Samsung Display Co., Ltd.

FIG. 5 is a cross-sectional view of a display device taken along a line I-I′ of FIG. 4 according to an embodiment of the present disclosure.

Referring to FIG. 5, the display device DD may include a display panel DP and a light control member PP on the display panel DP.

The display panel DP may include a base layer BS, a circuit layer DP-CL on the base layer BS, a display element layer DP-EL on the circuit layer DP-CL, and an encapsulation layer TFE on the display element layer DP-EL.

The display panel DP may be a light emitting type (or kind) of display panel. As an example, the display panel DP may be an organic electroluminescence display panel or a quantum dot light emitting display panel, however, it should not be limited thereto or thereby. According to an embodiment, the display panel DP may be a micro-LED display panel, a micro-OLED display panel, a nano-OLED display panel, or an LCD display panel. When the display panel DP is the LCD display panel, the display panel DP may further include a backlight unit to provide a light to the LCD display panel.

The base layer BS may be provided at a lowermost position of the display panel DP. The base layer BS may provide a base surface on which components except the base layer BS included in the display panel DP are stacked.

The base layer BS may include a synthetic resin layer and/or a glass layer. The base layer BS may include a first synthetic resin layer, a second synthetic resin layer, and an inorganic layer between the first and second synthetic resin layers. The synthetic resin layer may include a thermosetting resin. In some embodiments, the synthetic resin layer may be a polyimide-based resin layer, however, it should not be limited thereto or thereby. The synthetic resin layer may include at least one selected from an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin.

The circuit layer DP-CL may be on the base layer BS. The circuit layer DP-CL may include an insulating layer (e.g., an electrically insulating layer), a semiconductor pattern, a conductive pattern (e.g., an electrically conductive pattern), and a signal line. An insulating layer (e.g., an electrically insulating layer), a semiconductor layer, and a conductive layer (e.g., an electrically conductive layer) may be formed on the base layer BS by a coating and/or depositing process. Then, the insulating layer, the semiconductor layer, and the conductive layer may be selectively patterned through several photolithography processes. Accordingly, the semiconductor pattern, the conductive pattern, and the signal line included in the circuit element layer DP-CL may be formed. The circuit layer DP-CL may include a transistor, a buffer layer, and a plurality of insulating layers (e.g., a plurality of electrically insulating layers).

The display element layer DP-EL may include a pixel definition layer PDL, the light emitting element ED, and an encapsulation layer TFE on the light emitting element ED.

The pixel definition layer PDL may be on the circuit element layer DP-CL and may cover a portion of a first electrode EL1 further described below. Light emitting openings OH may be defined through the pixel definition layer PDL. At least a portion of the first electrode EL1 may be exposed through a corresponding light emitting opening of the light emitting openings OH of the pixel definition layer PDL.

The pixel definition layer PDL may be formed of a polymer resin. As an example, the pixel definition layer PDL may include a polyacrylate-based resin and/or a polyimide-based resin. In some embodiments, the pixel definition layer PDL may further include an inorganic material in addition to the polymer resin. As an example, the pixel definition layer PDL may include silicon nitride (SiNₓ), silicon oxide (SiOₓ), and/or silicon oxynitride (SiOₓN_{y}). In some embodiments, the pixel definition layer PDL may include a light absorbing material and/or a black pigment and/or dye. The pixel definition layer PDL including the black pigment and/or dye may be a black pixel definition layer. When the pixel definition layer PDL is formed, a carbon black may be used as the black pigment and/or dye, however, the present disclosure should not be limited.

The pixel definition layer PDL may define the light emitting areas PXA-B, PXA-G, and PXA-R. The light emitting areas PXA-B, PXA-G, and PXA-R may be distinguished from the non-light-emitting area NPXA by the pixel definition layer PDL.

The light emitting areas PXA-B, PXA-G, and PXA-R may have different sizes depending on the colors of the lights emitted therefrom. In the present embodiment, the size may mean a size when viewed from the plane defined by the first direction DR1 and the second direction DR2. In the display device DD, the blue light emitting area PXA-B may have the largest size, and the green light emitting PXA-G may have the smallest size, however, the present disclosure should not be limited thereto or thereby.

According to the display panel DP of embodiments of the present disclosure, the light emitting element ED may emit a source light. As an example, the source light may correspond to the blue light. The light emitting element ED may include a first electrode EL1, a second electrode EL2 on the first electrode EL1, and a functional layer OL between the first electrode EL1 and the second electrode EL2.

FIG. 5 schematically shows the functional layer OL as a single layer, however, the functional layer OL may include a plurality of functional layers such as a hole transport region, a light emitting layer, and an electron transport region. The light emitting layer may include a host and a dopant, which are organic electroluminescent materials, or may include the quantum dot according to the previously described embodiment and/or any suitable quantum dots generally available in the art.

As an example, the light emitting element ED may be alight emitting element having a Tandem structure including a plurality of light emitting stacks. Each of the light emitting stacks may include the light emitting layer. In embodiments, a light emitted from each of the light emitting stacks may be the blue light, however, the present disclosure should not be limited thereto or thereby. According to an embodiment, lights respectively emitted from the light emitting stacks may have different wavelengths from each other. As an example, at least one of the light emitting stacks may emit the blue light, and the other light emitting stacks may emit the green light. In embodiments, the light emitting element ED may emit a white light by the combination of the plurality of light emitting stacks that emit the lights in different wavelength ranges. A charge generation layer may be between the light emitting stacks adjacent to each other. Accordingly, when the light emitting element ED is the light emitting element having the Tandem structure, the functional layer OL may include the multiple light emitting stacks and the charge generation layer between the light emitting stacks.

FIG. 5 shows the functional layer OL as the single layer that is commonly provided over the light emitting areas PXA-B, PXA-G, and PXA-R, however, at least one of the layers included the functional layer OL may be provided after being patterned to respectively correspond to the light emitting areas PXA-B, PXA-G, and PXA-R by the pixel definition layer PDL.

The encapsulation layer TFE may cover the display element layer DP-EL. The encapsulation layer TFE may be a single layer or a multi-layer including a plurality of layers stacked one on another. As an example, the encapsulation layer TFE may include a first inorganic layer, an organic layer, and a second inorganic layer that are sequentially stacked. However, the present disclosure should not be limited thereto or thereby, and the encapsulation layer TFE may further include an inorganic layer and an organic layer. The encapsulation layer TFE may protect the display element layer DP-EL from external moisture and/or oxygen. Accordingly, the encapsulation layer TFE may improve the reliability of the display device DD.

The light control member PP may include a base substrate BL, a light control layer CCL under the base substrate BL, and a color filter layer CFL between the base substrate BL and the light control layer CCL, however, the present disclosure should not be limited thereto or thereby, and the color filter layer CFL may be omitted.

The base substrate BL may be provided at an uppermost position of the light control member PP. The base substrate BL may provide a base surface on which components included in the light control member PP are stacked except the base substrate BL. The base substrate BL may be a glass substrate, a metal substrate, and/or a plastic substrate, however, the present disclosure should not be limited thereto or thereby. According to an embodiment, the base substrate BL may be an inorganic layer, an organic layer, or a composite material layer.

The color filter layer CFL may be under the base substrate BL. The color filter layer CFL may include a plurality of filters CF1, CF2, and CF3 and a second barrier layer BFL2.

First, second, and third filters CF1, CF2, and CF3 may correspond to the blue light emitting area PXA-B, the green light emitting area PXA-G, and the red light emitting area PXA-R, respectively.

The first filter CF1 may transmit the first color light, the second filter CF2 may transmit the second color light, and the third filter CF3 may transmit the third color light. As an example, the first filter CF1 may be a blue filter, the second filter CF2 may be a green filter, and the third filter CF3 may be a red filter.

Each of the filters CF1, CF2, and CF3 may include a polymer photosensitive resin and a pigment and/or dye. The first filter CF1 may include a blue pigment and/or dye, the second filter CF2 may include a green pigment and/or dye, and the third filter CF3 may include a red pigment and/or dye, however, the present disclosure should not be limited thereto or thereby. According to an embodiment, the first filter CF1 may include the polymer photosensitive resin but may not include a pigment or dye. The first filter CF1 may be transparent. The first filter CF1 may be formed of a transparent photosensitive resin.

The color filter layer CFL may include a light blocking portion. The light blocking portion may be a black matrix. The light blocking portion may include an organic light blocking material and/or an inorganic light blocking material, which includes a black pigment and/or dye. The light blocking portion may prevent a light leakage phenomenon from occurring (or reduce a likelihood or occurrence thereof) and may define a boundary between the filters CF1, CF2, and CF3 adjacent to each other. In some embodiments, the light blocking portion may be formed as the blue filter. The light blocking portion may correspond to the non-light-emitting area NPXA.

The first filter CF1, the second filter CF2, and the third filter CF3 may overlap each other in the non-light-emitting area NPXA. In some embodiments, portions where the filters CF1, CF2, and CF3 overlap each other may prevent the light leakage from occurring (or reduce a likelihood or occurrence thereof) and may distinguish the boundary between the filters CF1, CF2, and CF3 adjacent to each other as the light blocking portion.

The light control layer CCL may include a plurality of light control portions CCP1, CCP2, and CCP3, a dividing pattern BMP allowing the light control portions CCP1, CCP2, and CCP3 to be distinguished from each other, and a first barrier layer BFL1.

The dividing pattern BMP may include a polymer resin and a liquid-repellent additive. The dividing pattern BMP may include a light absorbing material and/or a pigment and/or dye. As an example, the dividing pattern BMP may include a black pigment and/or a black dye to implement a black dividing pattern. When the black dividing pattern is formed, a carbon black may be used as the black pigment and/or dye, however, the present disclosure should not be limited.

The light control portions CCP1, CCP2, and CCP3 may include a first light control portion CCP1 transmitting the first color light, a second light control portion CCP2 converting the first color light to the second color light, and a third light control portion CCP3 converting the first color light to the third color light.

The second color light may have a longer wavelength than the first color light, and the third color light may have a longer wavelength than the first color light and the second color light. As an example, the first color light may be the blue light, the second color light may be the green light, and the third color light may be the red light.

The first light control portion CCP1 may include the scatterer SP (e.g., a light scatterer SP), the second light control portion CCP2 may include a first quantum dot QD1 and the scatterer SP, and the third light control portion CCP3 may include a second quantum dot QD2 and the scatterer SP. In embodiments, the first light control portion CCP1 may not include the quantum dot.

Because an energy band gap may be adjusted by adjusting a size of the core or shell of the first and second quantum dots QD1 and QD2 or an element ratio in the compound, lights of various suitable wavelengths may be obtained. The first quantum dot QD1 may convert the first color light to the second color light, and the second quantum dot QD2 may convert the first color light to the third color light. As an example, the first quantum dot QD1 may absorb the source light having the blue color and may emit the second color light having the green color, and the second quantum dot QD2 may absorb the source light having the blue color and may emit the third color light having the red color.

Descriptions of the quantum dots QD and QD-1 with reference to FIGS. 3A and 3B may be applied to the first and second quantum dots QD1 and QD2. In embodiments, the first and second quantum dots QD1 and QD2 may correspond to the quantum dots QD and QD-1 having an ACIGS/ZnS (Ag—Cu—In—Ga—S/ZnS) structure. The first and second quantum dots QD1 and QD2 may improve the color purity and the color reproducibility in a range where the first and second quantum dots QD1 and QD2 have the FWHM described herein. In embodiments, the light emitted from the first and second quantum dots QD1 and QD2 may travel in all (e.g., substantially all) directions, and thus, the light viewing angle may be improved. FIG. 5 shows structures in which the first and second quantum dots QD1 and QD2 have similar sizes to each other. However, these are merely examples, and the present disclosure should not be limited thereto or thereby. As an example, the first quantum dot QD1 that emits a light in a relatively short wavelength range may have a small average diameter compared to the second quantum dot QD2 that emits a light in a relatively long wavelength range. In the present disclosure, the average diameter may correspond to an arithmetic average value of diameters of a plurality of quantum dot particles. In embodiments, the diameter of the quantum dot particle may be an average value of a width of the quantum dot particle in a cross-section.

The scatterer SP may be an inorganic particle. As an example, the scatterer SP may include at least one selected from TiO₂, ZnO, Al₂O₃, SiO₂, and a hollow silica particle. The scatterer SP may include one selected from TiO₂, ZnO, Al₂O₃, SiO₂, and the hollow silica particle or may include two or more selected from TiO₂, ZnO, Al₂O₃, SiO₂, and the hollow silica, which are mixed together with each other.

The first light control portion CCP1, the second light control portion CCP2, and the third light control portion CCP3 may further include base resins BR1, BR2, and BR3 in which the quantum dots QD1 and QD2 and/or the scatterer SP are dispersed. According to an embodiment, the first light control portion CCP1 may include the scatterer SP dispersed in a first base resin BR1.

According to an embodiment, the blue light emitting area PXA-B corresponding to the first light emitting element ED that emits the blue light may have the largest size in the display device DD, and the green light emitting area PXA-G corresponding to the light emitting element ED that emits the green light may have the smallest size in the display device DD. The base resins BR1, BR2, and BR3 may be a medium in which the quantum dots QD and QD2 and the scatterer SP are dispersed and may include various suitable resin compositions that are generally referred to as a binder. As an example, the first, second, and third base resins BR1, BR2, and BR3 may be an acrylic-based resin, a urethane-based resin, a silicone-based resin, and/or an epoxy-based resin. The first, second, and third base resins BR1, BR2, and BR3 may be a transparent resin. According to an embodiment, the first base resin BR1, the second base resin BR2, and the third base resin BR3 may be the same as each other or different from each other.

The first barrier layer BFL1 may cover the light control portions CCP1, CCP2, CCP3. The first barrier layer BFL1 may prevent moisture and/or oxygen (which may hereinafter be referred to as moisture/oxygen) from entering. The first barrier layer BFL1 may be on the light control portions CCP1, CCP2, and CCP3 to prevent or reduce exposure of the light control portions CCP1, CCP2, and CCP3 to moisture/oxygen. The second barrier layer BFL2 may be between the light control portions CCP1, CCP2, and CCP3 and the color filter layer CFL.

The barrier layers BFL1 and BFL2 may include at least one inorganic layer. In some embodiments, the barrier layers BFL1 and BFL2 may include an inorganic material. As an example, the barrier layers BFL1 and BFL2 may include silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride and/or a metal thin film having light transmittance. In some embodiments, the barrier layers BFL1 and BFL2 may further include an organic layer. Each of the barrier layers BFL1 and BFL2 may include a single layer or a plurality of layers.

At least one of the first, second, and third light control portions CCP1, CCP2, and CCP3 of the display device DD may include the quantum dots QD and QD-1 (refer to FIGS. 3A-3B) according to embodiments of the present disclosure, and thus, the display device DD may have excellent color reproducibility. In some embodiments, the display device DD including the quantum dot according to embodiments of the present disclosure may have excellent optical characteristics and reliability.

Hereinafter, the quantum dot according to embodiments of the present disclosure will be described in more detail with reference to Examples and Comparative Examples. In addition, the examples shown below are to aid understanding of the subject matter of the present disclosure, and the scope of the present disclosure should not be limited thereto or thereby.

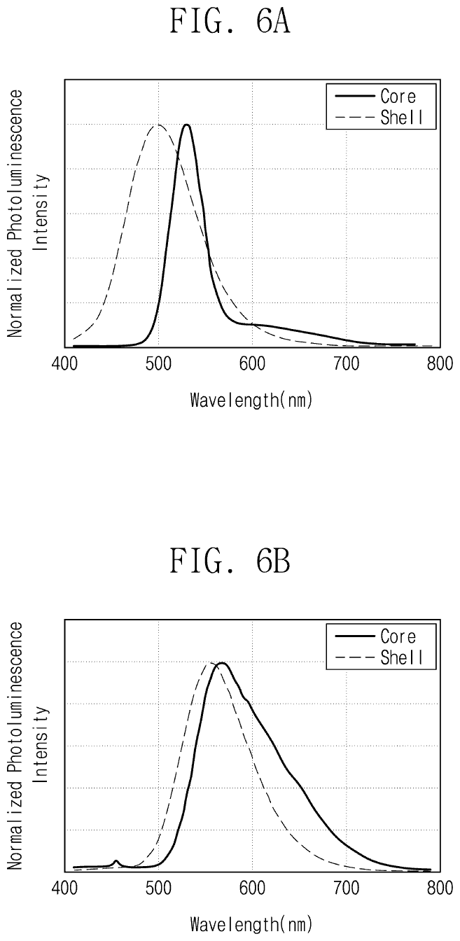

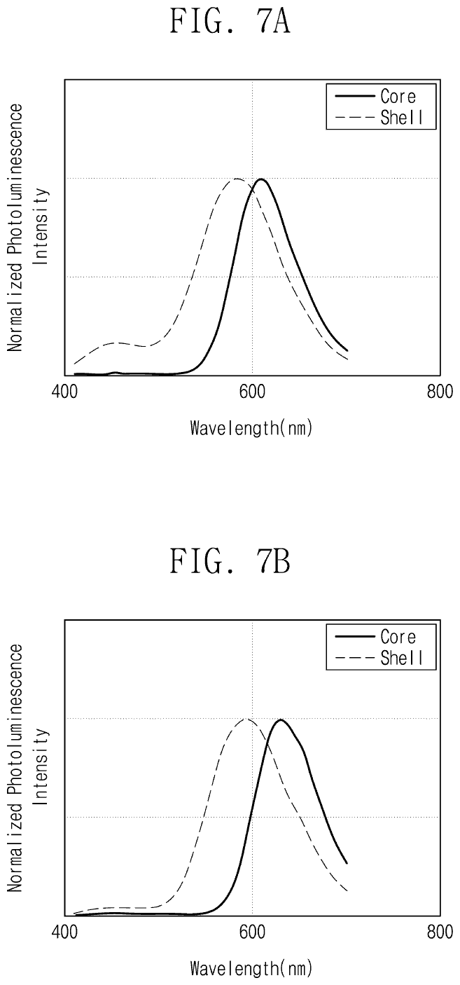

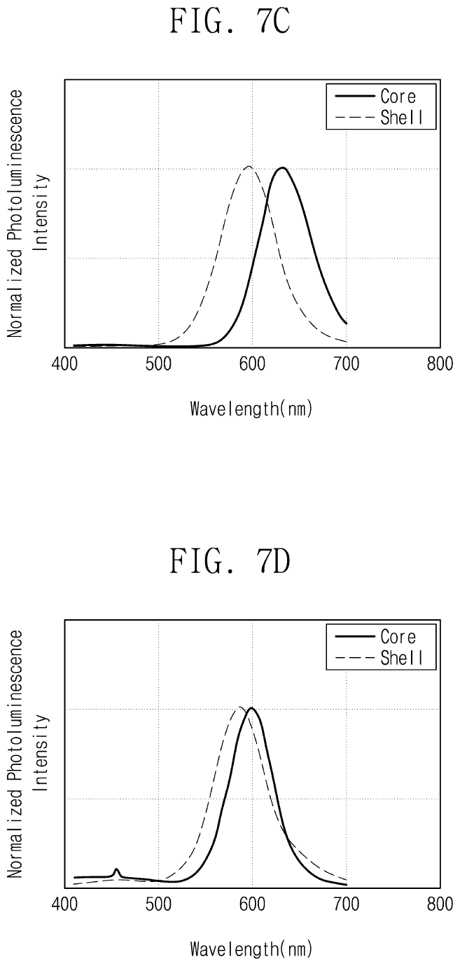

A quantum dot of Comparative Example 1, which is used in the evaluation shown in FIGS. 6A, 6B, and 7A-7D and Table 1, includes a core including silver (Ag), indium (In), gallium (Ga), and sulfur (S) and a shell surrounding the core and including zinc sulfide (ZnS). That is, the quantum dot of Comparative Example 1 was a quantum dot having a core-shell structure of AgInGaS/ZnS.

In addition, a quantum dot of Comparative Example 2 includes a core including copper (Cu), indium (In), gallium (Ga), and sulfur (S) and a shell surrounding the core and including zinc sulfide (ZnS). That is, the quantum dot of Comparative Example 2 was a quantum dot having a core-shell structure of CuInGaS₂/ZnS.

Each of the quantum dots of Examples 1 to 4 includes a core including silver (Ag), copper (Cu), indium (In), gallium (Ga), and sulfur (S) and a shell surrounding the core and including zinc sulfide (ZnS). That is, the quantum dots of Examples 1 to 4 were each Ag—Cu—In—Ga—S/ZnS core shell quantum dots. However, ratios of a number of moles of silver to copper in Embodiment Examples 1 to 4 are different from each other. In Examples 1 to 4, the ratios of the number of moles of silver to copper are 8:2, 6:4, 4:6, and 2:8, respectively.

FIG. 6A is a graph illustrating a photoluminescence spectrum with respect to the quantum dot according to Comparative Example 1. FIG. 6B is a graph illustrating a photoluminescence spectrum with respect to the quantum dot according to Comparative Example 2. FIGS. 7A-7D are graphs illustrating a photoluminescence spectrum with respect to the quantum dots according to embodiments of the present disclosure. In FIGS. 6A, 6B, and 7A-7D, a vertical axis indicates a light emission intensity, and a horizontal axis indicates a photoluminescence wavelength.

In FIGS. 6A, 6B, and 7A-7D, a graph of “core” indicated by a solid line corresponds to a case where only the core is included, and a graph of “shell” indicated by a dotted line corresponds to a case where the quantum dot includes the core and the shell surrounding the outside of the core.

Table 1 below shows measurement results of a photoluminescence wavelength (PL) peak and a FWHM of the quantum dots of the Comparative Examples and Examples.

For the convenience of explanation, a value obtained by subtracting the FWHM of the quantum dot in which only the core is formed from the FWHM of the quantum dot in which the core and the shell are formed (core/shell FWHM−core FWHM) in the comparative examples or the Embodiment examples is referred to as “a variation of the FWHM” of the comparative examples or the Embodiment examples. In this case, ‘+’ in front of the variation of the FWHM indicates an increase, and ‘−’ in front of the variation of the FWHM indicates a decrease.

TABLE 1

| | | | | Variation |
|---|---|---|---|---|
| | Shell | PL | FWHM | of |
| | presence/absence | peak (nm) | (nm) | FWHM (nm) |
| Comparative | Core | 529 | 39 | +50 |
| example 1 | Core/shell | 505 | 89 | |
| Comparative | Core | 563 | 99 | −16 |
| example 2 | Core/shell | 557 | 83 | |
| Embodiment | Core | 607 | 76 | +25 |
| example 1 | Core/shell | 585 | 101 | |
| Embodiment | Core | 629 | 77 | +23 |
| example 2 | Core/shell | 595 | 100 | |
| Embodiment | Core | 633 | 64 | +5 |
| example 3 | Core/shell | 595 | 69 | |
| Embodiment | Core | 598 | 54 | +10 |
| example 4 | Core/shell | 587 | 64 | |

Referring to FIG. 6A and Table 1, the FWHM of the “core” of Comparative Example 1 corresponds to a relatively small value (39 nm) when compared with those of the other Comparative Example and Examples. However, the variation (+50 nm) of the FWHM of Comparative Example 1 is relatively large compared with those of other Comparative example and Embodiment examples. In the case of Comparative Example 1, when the shell including zinc sulfide (ZnS) is grown on the core including AgInGaS, the shell does not have enough thickness after the growth. Because the lattice spacing of the AgInS₂ compound and the AgGaS₂ compound are about 5.90 Å and about 5.76 Å respectively, and the lattice spacing of the ZnS compound is about 5.47 Å, there is a difference in lattice spacing between the compound included in the core and the compound included in the shell, and thus, gallium escapes from the core and moves to the shell. Accordingly, the FWHM increases, and the color reproducibility of the quantum dot decreases.

Referring to FIG. 6B and Table 1, the FWHM (99 nm) of the “core” of Comparative Example 2 corresponds to a relatively large value. However, the variation (−16 nm) of the luminescence FWHM of Comparative Example 2 is relatively smaller than those of Comparative Example 1 and Embodiment examples 1 and 2. As described above, because the lattice spacing of the CuInS₂ compound and the CuGaS₂ compound are about 5.52 Å and about 5.33 Å, respectively, and the lattice spacing of the ZnS compound is about 5.47 Å, the lattice spacing of the compound included in the core is similar to the lattice spacing of the compound included in the shell. Accordingly, the compound included in the core does not move, and thus, the shell may have a sufficient thickness after the growth.

That is, the quantum dot including the core including the AgInGaS compound as Comparative Example 1 has a narrow FWHM, however, it is difficult to form the ZnS shell. In addition, in the case of the quantum dot including the core including the CuInGaS compound as Comparative Example 2, the FWHM of the core is large, however, the zinc sulfide shell surrounding the core has a sufficient thickness after the growth. Accordingly, even after the growth of the shell surrounding the core, the change in the FWHM may be small, and the FWHM decreases.

The quantum dots of Embodiment examples 1 to 4 include the core including silver, copper, indium, gallium, and sulfur and the shell surrounding the core and zinc sulfide (ZnS). Different from the quantum dots of Comparative Example 1 and Comparative Example 2, the quantum dots of Embodiment examples 1 to 4 include the core including both silver and copper. That is, the quantum dots of Embodiment examples 1 to 4 may be the quantum dot having the core/shell structure that contains Ag/Cu/In/Ga/S as the core and ZnS as the shell.

Referring to FIGS. 7A-7D and Table 1, the cores of Embodiment examples 1 to 4 respectively have the FWHM (nm) of 76 nm, 77 nm, 64 nm, and 54 nm, which are smaller than the FWHM (99 nm) of the quantum dot including only the core of Comparative Example 2 including only the core.

In addition, the variation of the FWHM of Examples 1 to 3 increases but is smaller than the variation (+50 nm) of the FWHM of Comparative Example 1. In addition, the variation of the FWHM of Embodiment example 4 corresponds to an increasing value of +10 nm.

Referring to FIG. 7D and Table 1, even though the shell is further formed on the core, a change in the photoluminescence wavelength of the quantum dot of Embodiment example 4 is very little. That is, the stability of the shell is sufficiently secured, and characteristics of the core of the quantum dot is well maintained.

According to embodiments of the present disclosure, the core includes all of copper, indium, gallium, sulfur, and silver, and thus has the small FWHM. In addition, as the quantum dot includes the core described above, the shell including zinc sulfide may be suitably or sufficiently grown, and thus, the variation of the FWHM between the case including the shell and the case without including the shell is small.

Therefore, in the case where the quantum dot according to embodiments of the present disclosure is included in the light control portions CCP (refer to FIG. 5) of the display device DD (refer to FIG. 5), excellent color reproducibility and reliability may be secured.

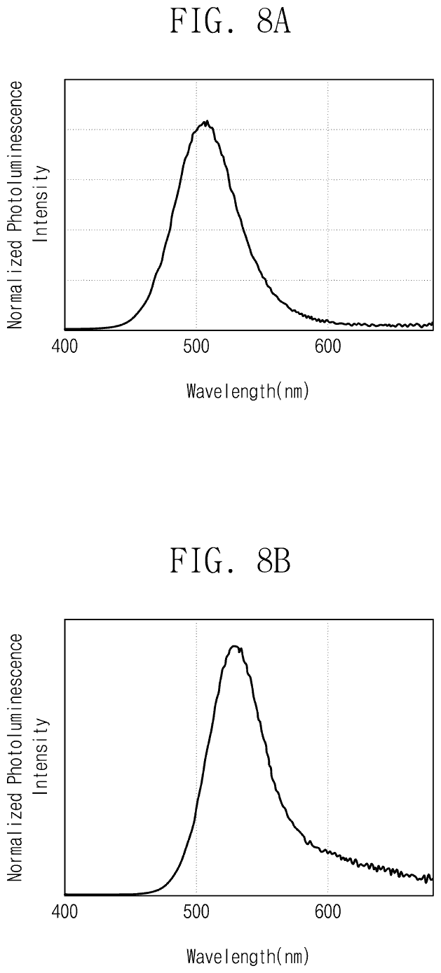

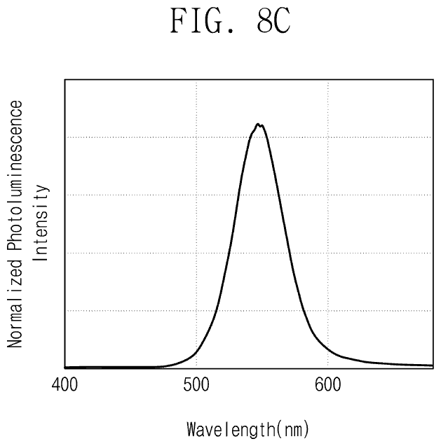

FIGS. 8A-8C are graphs illustrating a photoluminescence (PL) spectrum with respect to quantum dots according to embodiments of the present disclosure. Characteristics of the quantum dots of Embodiment examples 5 to 7 will be described with reference to FIGS. 8A-8C and Table 2.

The quantum dot of Embodiment examples 5 to 7 may correspond to the quantum dots QD and QD-1 described with reference to FIGS. 3A-3B. That is, the quantum dots of Embodiment examples 5 to 7 may be the quantum dot containing Ag/Cu/In/Ga/S as the core and ZnS as the shell.

A composition ratio (molar ratio) of silver, copper, indium, gallium, and sulfur contained in each core included in the quantum dots of Embodiment examples 5 to 7 is as follows.

Composition ratio of the core of Embodiment example 5: Ag_{0.01}Cu_{0.99}In_{0.2}Ga_{0.8}S₂

Composition ratio of the core of Embodiment example 6: Ag_{0.03}Cu_{0.97}In_{0.2}Ga_{0.8}S₂

Composition ratio of the core of Embodiment example 7: Ag_{0.1}Cu_{0.9}In_{0.35}Ga_{0.65}S₂

The photoluminescence wavelength may be adjusted by adjusting a size of particles of the quantum dots of Embodiment examples 5 to 7. As an example, the core of the quantum dot of Embodiment example 5 has a diameter from about 1.6 nm to about 3.2 nm, and the quantum dot of Embodiment example 5 has a diameter from about 3.2 nm to about 5.2 nm. The diameter of the quantum dot corresponds to an overall diameter including the core and the shell.

The core of the quantum dot of Embodiment example 6 has a diameter from about 1.8 nm to about 3.2 nm, and the quantum dot of Embodiment example 6 has a diameter from about 3.3 nm to about 5.7 nm. The core of the quantum dot of Embodiment example 7 has a diameter from about 1.7 nm to about 2.9 nm, and the quantum dot of Embodiment example 7 has a diameter from about 3.2 nm to about 5.4 nm.

Each of the quantum dots according to the present embodiment may correspond to the quantum dot that emits the green light having the FWHM equal to or greater than about 25 nm and equal to or smaller than about 60 nm.

Table 2 below shows a photoluminescence wavelength (PL) peak, a FWHM, a photoluminescence quantum yield (PLQY), and a photostability of the quantum dots of Embodiment examples 5 to 7.

The photoluminescence quantum yield (PLQY) refers to the number of photons emitted by a material compared to the number of photons absorbed by the material, and the higher the photoluminescence quantum yield, the more efficiently the material may emit the energy it has absorbed. In embodiments, the photostability refers to the ability of the quantum dot to maintain its luminescence properties over time when exposed to light.

In embodiments of the present disclosure, the photoluminescence quantum yield (PLQY) and the photostability of the quantum dot of the Embodiment examples are measured by “QE-2100”, which is a quantum efficiency measurement equipment provided by Donga Otsuka™.

In embodiments, in measuring the photoluminescence quantum yield, a reference solution is placed in an integrating sphere, and a light having a wavelength of about 450 nm is irradiated to collect the photoluminescence spectrum, and similarly, a sample solution containing the quantum dot according to embodiments of the present disclosure is placed in the integrating sphere, and a light having a wavelength of about 450 nm is irradiated to collect the photoluminescence spectrum. An intensity of a light source spectrum decreases by the amount absorbed in the sample solution compared to the reference solution, and an intensity of the emitted light increases compared to a reference spectrum. In embodiments, the decreased or increased intensity of the light source spectrum are converted to the number of photons using the spectral intensity by wavelengths of the integrating sphere to calculate the photoluminescence quantum yield.

In embodiments, in measuring the photostability, an initial photon-conversion efficiency (PCE) is measured after producing a polymer film containing about 30 wt % of the quantum dot according to embodiments of the present disclosure, and a value of the photon-conversion efficiency, which is changed by irradiating the polymer film with the blue light of about 200 nit for 1500 hours, is measured. The blue light used to measure the photostability has a photoluminescence wavelength of about 450 nm.

Table 2 below shows the photoluminescence wavelength (PL) peak, the FWHM, the photoluminescence quantum yield (PLQY), and the photostability of the quantum dots of Embodiment examples 5 to 7.

TABLE 2

| | | | | Photostability |
|---|---|---|---|---|
| | PL peak (nm) | FWHM (nm) | PLQY (%) | (%) |
| Embodiment | 508 | 54 | 96 | 95 |
| example 5 | | | | |
| Embodiment | 530 | 50 | 88 | 94 |
| example 6 | | | | |
| Embodiment | 550 | 47 | 92 | 93 |
| example 7 | | | | |

Referring to Table 2, each of the quantum dots of Embodiment examples 5 to 7 has a full-width at half-maximum (FWHM) equal to or smaller than about 60 nm. In more detail, because the full-width at half-maximum (FWHM) is equal to or smaller than about 55 nm, the quantum dots according to embodiments of the present disclosure may exhibit high color purity compared to comparative examples 1 and 2. In embodiments, the quantum dots of Embodiment examples 5 to 7 correspond to test examples in which the composition ratio (molar ratio) of gallium to indium is set high and the size of the quantum dot particles is adjusted. Therefore, it is observed that the quantum dots of Embodiment examples 5 to 7 have a large band gap equal to or greater than about 500 nm and equal to or smaller than about 550 nm.

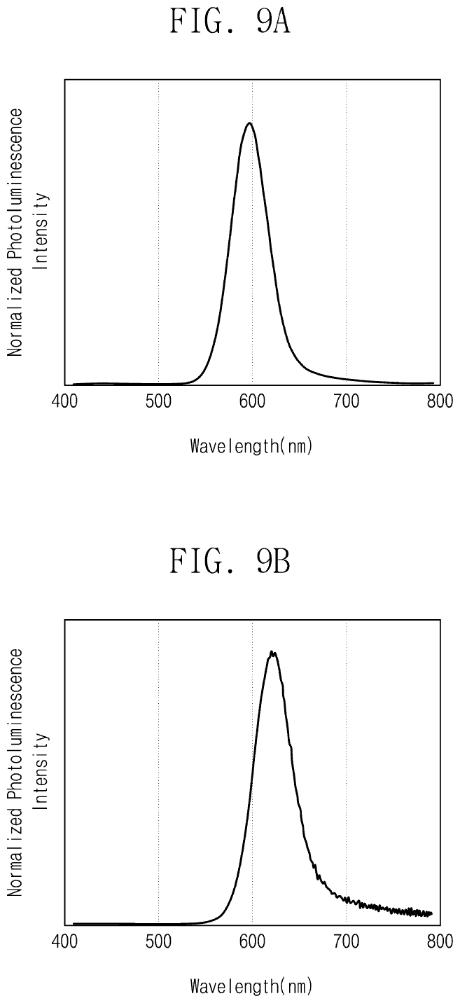

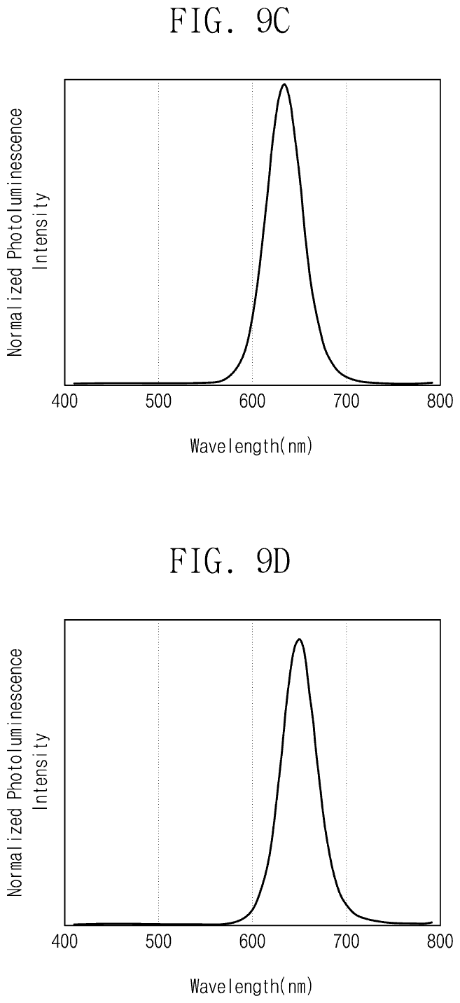

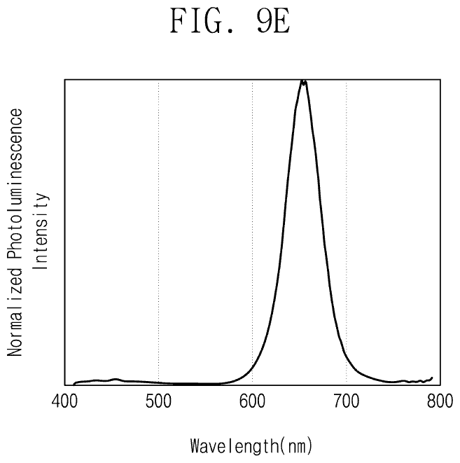

FIGS. 9A-9E are graphs illustrating a photoluminescence (PL) spectrum with respect to quantum dots according to embodiments of the present disclosure. Characteristics of the quantum dots of Embodiment examples 8 to 12 will be described with reference to FIGS. 9A-9E and Table 3.

The quantum dot of Embodiment examples 8 to 12 may correspond to the quantum dots QD and QD-1 described with reference to FIGS. 3A-3B. That is, the quantum dots of Embodiment examples 8 to 12 may the quantum dot containing Ag/Cu/In/Ga/S as the core and ZnS as the shell.

A composition ratio (molar ratio) of silver, copper, indium, gallium, and sulfur contained in each core included in the quantum dots of Embodiment examples 8 to 12 is as follows.

Composition ratio of the core of Embodiment example 8: Ag_{0.01}Cu_{0.99}In_{0.3}Ga_{0.7}S₂

Composition ratio of the core of Embodiment example 9: Ag_{0.03}Cu_{0.97}In_{0.4}Ga_{0.6}S₂

Composition ratio of the core of Embodiment example 10: Ag_{0.05}Cu_{0.95}In_{0.4}Ga_{0.6}S₂

Composition ratio of the core of Embodiment example 11: Ag_{0.1}Cu_{0.9}In_{0.35}Ga_{0.65}S₂

Composition ratio of the core of Embodiment example 12: Ag_{0.2}Cu_{0.8}In_{0.3}Ga_{0.7}S₂

The photoluminescence wavelength may be adjusted by adjusting a size of quantum dot particles of the quantum dots of Embodiment examples 8 to 12.

The core of the quantum dot of Embodiment example 8 has a diameter from about 3.8 nm to about 5.8 nm, and the quantum dot of Embodiment example 8 has a diameter from about 5.5 nm to about 7.9 nm. The core of the quantum dot of Embodiment example 9 has a diameter from about 4.4 nm to about 6.6 nm, and the quantum dot of Embodiment example 9 has a diameter from about 5.8 nm to about 8.6 nm. The core of the quantum dot of Embodiment example 10 has a diameter from about 4.4 nm to about 6.4 nm, and the quantum dot of Embodiment example 10 has a diameter from about 6.2 nm to about 9.2 nm. The core of the quantum dot of Embodiment example 11 has a diameter from about 4.4 nm to about 6.6 nm, and the quantum dot of Embodiment example 11 has a diameter from about 6.2 nm to about 9.0 nm. The core of the quantum dot of Embodiment example 12 has a diameter from about 4.7 nm to about 6.7 nm, and the quantum dot of Embodiment example 11 has a diameter from about 6.6 nm to about 9.8 nm.

Each of the quantum dots according to the present embodiments may correspond to the quantum dot that emits the red light having the FWHM equal to or smaller than about 60 nm.

Table 3 below shows a photoluminescence wavelength (PL) peak, a FWHM, a photoluminescence quantum yield (PLQY), and a photostability of the quantum dots of Embodiment examples 8 to 12.

TABLE 3

| | | | | Photostability |
|---|---|---|---|---|
| | PL peak (nm) | FWHM (nm) | PLQY (%) | (%) |
| Embodiment | 596 | 46 | 92 | 90 |
| example 8 | | | | |
| Embodiment | 628 | 48 | 91 | 92 |
| example 9 | | | | |
| Embodiment | 634 | 43 | 93 | 89 |
| example 10 | | | | |
| Embodiment | 648 | 42 | 92 | 91 |
| example 11 | | | | |
| Embodiment | 655 | 42 | 91 | 90 |
| example 12 | | | | |

Referring to Table 3, each of the quantum dots of Embodiment examples 8 to 12 has a full-width at half-maximum (FWHM) equal to or smaller than about 60 nm. In more detail, the full-width at half-maximum (FWHM) corresponds to a narrow FWHM of about 50 nm or less and exhibits high color purity compared to comparative examples 1 and 2. Referring to the photoluminescence wavelength of Embodiment examples 8 to 12, when a ratio of indium to gallium is adjusted under the condition that the diameter of the quantum dot is equal to or greater than about 5 nm, it is observed that the quantum dots having a small band gap value equal to or greater than about 580 nm and equal to or smaller than about 660 nm are formed as the ratio of indium to gallium increases.

In addition, referring to the FWHM of Embodiment examples 8 to 12, when the number of moles of silver is set in a range of about 1% to about 20% of the number of moles of copper, it is observed that the FWHM has a small value equal to or smaller than about 50 nm.

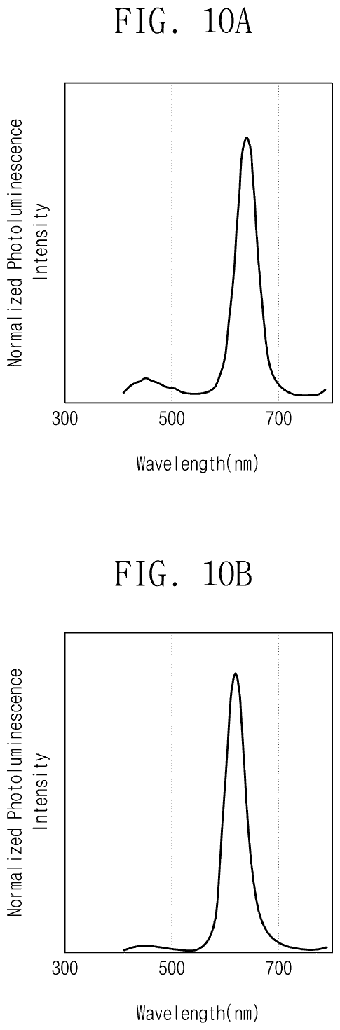

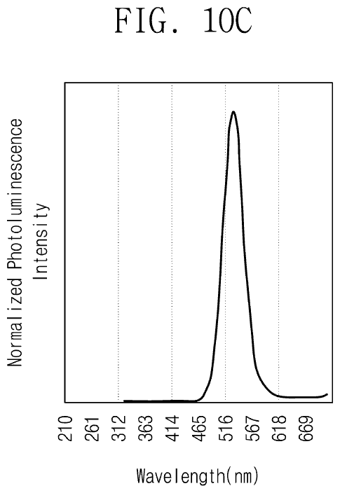

FIGS. 10A-10C are graphs illustrating a photoluminescence (PL) spectrum with respect to quantum dots according to embodiments of the present disclosure. Characteristics of the quantum dots of Embodiment examples 13 to 15 will be described with reference to FIGS. 10A-10C and Table 4.

The quantum dot of Embodiment examples 13 to 15 may correspond to the quantum dots QD and QD-1 described with reference to FIGS. 3A-3B. That is, the quantum dots of Embodiment examples 13 to 15 may be the quantum dot containing Ag/Cu/In/Ga/S as the core and ZnS as the shell.

A composition ratio (molar ratio) of silver, copper, indium, gallium, and sulfur contained in each core included in the quantum dots of Embodiment examples 13 to 15 is as follows. When compared to the quantum dots of Embodiment examples 8 to 12, the quantum dots of Embodiment examples 13 to 15 correspond to a case where the ratio of silver contained in the core is set to be smaller. That is, the quantum dots of Embodiment examples 13 to 15 were prepared under the condition that the core contains a very small amount of silver.

Composition ratio (mole ratio) of the core of Embodiment example 13: Ag_{0.001}Cu_{0.999}In_{0.3}Ga_{0.7}S₂

Composition ratio (mole ratio) of the core of Embodiment example 14: Ag_{0.002}Cu_{0.998}In_{0.3}Ga_{0.7}S₂

Composition ratio (mole ratio) of the core of Embodiment example 15: Ag_{0.005}Cu_{0.995}In_{0.2}Ga_{0.8}S₂

Table 4 below shows the composition ratio (mass ratio) of silver, copper, indium, gallium, and sulfur contained in each core included in the quantum dots of Embodiment examples 13 to 15. The mass ratio in Table 4 below is rounded and expressed to three digits after the decimal point.

TABLE 4

| | | | | | | Indium:galli- |
|---|---|---|---|---|---|---|
| | Silver | Copper | Indium | Gallium | Sulfur | um |
| Embodiment | 0.108 | 63.482 | 34.445 | 48.806 | 64.120 | 0.706 |
| example 13 | | | | | | |
| Embodiment | 0.216 | 63.419 | 34.445 | 48.806 | 64.120 | 0.706 |
| example 14 | | | | | | |
| Embodiment | 0.539 | 63.228 | 22.964 | 55.778 | 64.120 | 0.412 |
| example 15 | | | | | | |

The core of the quantum dot of Embodiment example 13 has a diameter from about 5.8 nm to about 7.6 nm, and the quantum dot of Embodiment example 13 has a diameter from about 7.4 nm to about 9.8 nm. The core of the quantum dot of Embodiment example 14 has a diameter from about 5.6 nm to about 7.4 nm, and the quantum dot of Embodiment example 14 has a diameter from about 7.9 nm to about 10.1 nm. The core of the quantum dot of Embodiment example 15 has a diameter from about 3.9 nm to about 5.1 nm, and the quantum dot of Embodiment example 15 has a diameter from about 5.0 nm to about 7.0 nm. Table 5 below shows a photoluminescence wavelength (PL) peak, a FWHM, a photoluminescence quantum yield (PLQY), and a photostability of the quantum dots of Embodiment examples 13 to 15.

TABLE 5

| | | | | Photostability |
|---|---|---|---|---|
| | PL peak (nm) | FWHM (nm) | PLQY (%) | (%) |
| Embodiment | 642 | 47 | 92 | 90 |
| example 13 | | | | |
| Embodiment | 622 | 45 | 95 | 90 |
| example 14 | | | | |
| Embodiment | 526 | 41 | 90 | 90 |
| example 15 | | | | |

Referring to Table 5, each of the quantum dots of Embodiment examples 13 to 15 has a full-width at half-maximum (FWHM) equal to or smaller than about 60 nm. In more detail, the full-width at half-maximum (FWHM) corresponds to a narrow FWHM of about 50 nm or less and exhibits high color purity compared to comparative examples 1 and 2.

Although embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present disclosure shall be determined according to the attached claims, and equivalents thereof.

1. A quantum dot comprising:
a core comprising copper, indium, gallium, silver, and sulfur; and
a shell surrounding the core and comprising zinc sulfide (ZnS).

2. The quantum dot of claim 1, wherein the quantum dot emits a green light having a center wavelength equal to or greater than about 500 nm and equal to or smaller than about 550 nm, and the quantum dot comprising the core and the shell has a diameter equal to or greater than about 2 nm and equal to or smaller than about 4 nm, and a ratio of a number of moles of the silver to a sum of a number of moles of the silver and the copper is equal to or greater than about 0.001 and equal to or smaller than about 0.200.

3. The quantum dot of claim 1, wherein the quantum dot emits a red light having a center wavelength equal to or greater than about 580 nm and equal to or smaller than about 660 nm, and the quantum dot comprising the core and the shell has a diameter equal to or greater than about 5 nm and equal to or smaller than about 10 nm, and a ratio of a number of moles of the silver to a sum of a number of moles of the silver and the copper is equal to or greater than about 0.001 and equal to or smaller than about 0.200.

4. The quantum dot of claim 1, wherein a light emitted from the quantum dot has a full-width at half-maximum (FWHM) equal to or greater than about 25 nm and equal to or smaller than about 60 nm.

5. The quantum dot of claim 1, further comprising at least one outer shell surrounding the shell, and the outer shell comprises ZnSe, ZnS, ZnTe, ZnO, ZnMg, ZnMgSe, ZnMgS, ZnMgAg, GaSe, GaTe, GaP, GaAs, GaSb, InAs, InSb, AlP, AlAs, AlSb, MnS, MnSe, MgS, and/or MgSe.

6. The quantum dot of claim 5, wherein the shell has a thickness of about 0.5 nm to about 3 nm, and the outer shell has a thickness of about 0.5 nm to about 4 nm.

7. The quantum dot of claim 5, wherein the outer shell has a thickness greater than a thickness of the shell.

8. The quantum dot of claim 1, wherein a ratio of a mass of the shell to a sum of masses of the core and the shell is equal to or greater than about 0.2 and equal to or smaller than about 0.8.

9. The quantum dot of claim 1, further comprising an organic ligand and/or a metal halide ligand bound to a surface of the quantum dot.

10. The quantum dot of claim 1, wherein the quantum dot emits a green light having a full-width at half-maximum (FWHM) equal to or greater than about 25 nm and equal to or smaller than about 60 nm and a center wavelength equal to or greater than about 500 nm and equal to or smaller than about 550 nm or a red light having a full-width at half-maximum (FWHM) equal to or greater than about 25 nm and equal to or smaller than about 60 nm and having a center wavelength equal to or greater than about 580 nm and equal to or smaller than about 660 nm, and a ratio of a mass of the gallium to a mass of the indium is within a range of about 0.2 to about 2.0.

11. A display device comprising:
a display panel providing a source light; and
a light control member on the display panel and comprising a light control layer comprising a plurality of light control portions and a dividing pattern allowing the light control portions to be distinguished from each other, at least one of the light control portions comprising a quantum dot, wherein the quantum dot comprises a core comprising copper, indium, gallium, silver, and sulfur and a shell surrounding the core and comprising zinc sulfide (ZnS).

12. The display device of claim 11, wherein the quantum dot emits a green light having a full-width at half-maximum (FWHM) equal to or greater than about 25 nm and equal to or smaller than about 60 nm and a center wavelength equal to or greater than about 500 nm and equal to or smaller than about 550 nm, and a ratio of a number of moles of the silver to a sum of a number of moles of the silver and the copper is equal to or greater than about 0.01 and equal to or smaller than about 0.10.

13. The display device of claim 11, wherein the quantum dot emits a red light having a full-width at half-maximum (FWHM) equal to or greater than about 25 nm and equal to or smaller than about 60 nm and a center wavelength equal to or greater than about 580 nm and equal to or smaller than about 660 nm, and a ratio of a number of moles of the silver to a sum of a number of moles of the silver and the copper is equal to or greater than about 0.01 and equal to or smaller than about 0.20.

14. The display device of claim 11, wherein a light emitted from the quantum dot has a full-width at half-maximum (FWHM) equal to or greater than about 25 nm and equal to or smaller than about 50 nm, and a ratio of a number of moles of the silver to a sum of a number of moles of the silver and the copper is equal to or greater than about 0.001 and equal to or smaller than about 0.05.

15. The display device of claim 11, wherein the core comprises, based on a total weight of the core of about 100 wt %, the copper equal to or greater than about 5 wt % and equal to or smaller than about 20 wt %, the indium equal to or greater than about 10 wt % and equal to or smaller than about 30 wt %, the gallium equal to or greater than about 10 wt % and equal to or smaller than about 40 wt %, the sulfur equal to or greater than about 30 wt % and equal to or smaller than about 60 wt %, and the silver equal to or greater than about 5 wt % and equal to or smaller than about 30 wt %.

16. The display device of claim 11, wherein the light control member further comprises a base substrate and a color filter layer comprising a plurality of filters transmitting lights having different wavelengths, the light control portions are between the display panel and the color filter layer, and the color filter layer is between the light control portions and the base substrate.

17. The display device of claim 11, wherein the light control portions comprise:
a first light control portion that transmits the source light;
a second light control portion that converts the source light to a second color light and emitting the second color light; and
a third light control portion that converts the source light to a third color light and emits the third color light, the source light is a blue light, and the second and third light control portions comprise the quantum dot.

18. The display device of claim 17, wherein the second color light is a green light having a center wavelength equal to or greater than about 500 nm and equal to or smaller than about 550 nm, and the quantum dot emits a green light having a full-width at half-maximum (FWHM) equal to or greater than about 25 nm and equal to or smaller than about 60 nm.

19. The display device of claim 17, wherein the third color light has a center wavelength equal to or greater than about 580 nm and equal to or smaller than about 660 nm, and the quantum dot emits a red light having a full-width at half-maximum (FWHM) equal to or greater than about 25 nm and equal to or smaller than about 60 nm.

20. The display device of claim 11, wherein the quantum dot further comprises at least one outer shell surrounding the shell, and the outer shell comprises ZnSe, ZnS, ZnTe, ZnO, ZnMg, ZnMgSe, ZnMgS, ZnMgAg, GaSe, GaTe, GaP, GaAs, GaSb, InAs, InSb, AlP, AlAs, AlSb, MnS, MnSe, MgS, or MgSe.
